(19) United States
(12) Patent Application Publication
(10) Pub. No.: US 2009/0213923 A1
(43) Pub. Date: Aug. 27, 2009

(54) Method and apparatus for channel detection

(75) Inventors: Xiao-Ming Chen, Hannover (DE); Oliver Theis, Hannover (DE)

Correspondence Address: Thomson Licensing LLC, P.O. Box 5312, Two Independence Way, PRINCETON, NJ, 08543-5312, US

(73) Assignee: Thomson Licensing

(21) Appl. No.: 12/378,941

(22) Filed: Feb. 20, 2009

(30) Foreign Application Priority Data
Feb. 22, 2008 (EP) 08101914.3

(51) Int. Cl. H04L 27/01; H03M 13/23; G06F 11/08; H04L 5/12

(52) U.S. Cl. 375/233; 714/792; 375/262; 375/232; 714/E11.03

(57) ABSTRACT

The invention proposes a method for joint detection and channel decoding of binary data employing a trellis-based detector where the trellis describes RLL encoding, NRZI preceding, the influence of the channel, and PR equalization. In order to improve performance for the case of exchanging soft information with an outer soft-in soft-out channel decoder or ECC decoder under the presence of correlated noise, the trellis is extended to also comprise and model a Noise Prediction.

### TECHNICAL FIELD

The present invention relates to channel encoding and decoding of binary data. This invention relates to joint bit detection and RLL decoding and noise prediction.

### BACKGROUND ART

For high-density optical storage systems, a so-called partial-response or PR maximum likelihood technique also known as PRML is employed for reliable bit detection. In PRML, a PR-equalizer is used to shape the overall channel impulse response to a desired PR target. Noise samples at the equalizer output are correlated, and the performance degradation due to correlated noise becomes significant with increased storage density. Therefore, to perform noise whitening, noise-predictive maximum likelihood detection was proposed in J. D. Coker et al, “Noise-predictive maximum likelihood (NPML) detection,” IEEE Trans. Magnet., vol. 34, pp. 110-117, January 1998 [1].

In order to effectively exchange soft information, also called reliability information, with an outer soft-in soft-out (SISO) channel or ECC decoder, joint bit detection and runlength limited (RLL) decoding has been investigated in F. Zhao et al, “Joint turbo channel detection and RLL decoding for (1, 7) coded partial response recording channels,” IEEE ICC'03, pp. 2919-2923, 2003, and in M. Noda et al, “An 8-state DC-controllable run-length-limited code for the optical-storage channel,” JJAP, vol. 44, No. 5B, pp. 3462-3466, 2005.

Accordingly, the concatenation of RLL encoder, non-return-to-zero inverted (NRZI) precoder, and PR channel is interpreted as an equivalent RLL-NRZI-PR channel, which can be represented by an RLL-NRZI-PR super-trellis. In this, “trellis” is an abbreviation known in the field, that stands for “tree-like structure”. With this super-trellis, soft-in soft-out decoding algorithms such as BCJR, SOVA, or Max-Log-MAP can be applied to perform joint bit detection and RLL decoding.

### SUMMARY OF THE INVENTION

This invention starts by recognizing that previous super-trellis based approaches only considered ideal PR-channels. In the presence of correlated noise due to a PR equalizer, an RLL-NRZI-PR super-trellis based detector may not deliver satisfying bit error rate (BER) performance, without taking noise prediction into account. In addition, the quality of soft outputs from the RLL-NRZI-PR super-trellis based detector may be poor resulting in an ineffective soft-information exchange with an outer soft-in soft-out channel or ECC decoder such as a LDPC decoder or a turbo decoder for error correction.

Amongst others, the invention aims at how to perform joint bit detection and RLL decoding in the presence of colored noise at a reasonable complexity; and at how to effectively perform iterative soft-information exchange between the joint bit detector and RLL decoder with an outer soft-in soft-out decoder.

With other words, the concept of super-trellis detection is extended in this invention to additionally encompass noise predictive detection. In addition, to keep the detector complexity reasonably low, reduced-state variations of the super-trellis based detector are derived, based on the principle of delayed decision feedback sequence estimation.

In the presence of a noise predictor (NP), the concatenation of RLL encoder, NRZI precoder, PR channel, and noise predictor is here interpreted as an equivalent RLL-NRZI-PR-NP channel. Consequently, a super-trellis representing this RLL-NRZI-PR-NP channel is employed here to perform joint bit detection and RLL decoding.

Typically, the equivalent RLL-NRZI-PR-NP channel corresponds to an overall impulse response having many taps, i.e. of high degree. Because of this, reduced-state variations of the full-state RLL-NRZI-PR-NP super-trellis are derived and used here. With these reduced super-trellises, the part of the overall impulse response that is not covered within the trellis, is taken into account by tracing back surviving paths in the reduced-state super-trellis. In this, the memory length covered by the trellis is a design parameter K that trades off complexity and performance. In this context, appropriate soft-in soft-out algorithms are SOVA or Max-Log-MAP, because survivors exist there that can be traced back.

Using the RLL-NRZI-PR-NP super-trellis, or reduced-state variations thereof, allows that iterative soft-information exchange is carried out between the joint bit detector and RLL decoder and an outer soft-in soft-out decoder employing the turbo principle.

With other words: In this invention, instead of an impulse response h of a PR channel, an impulse response g which is a convolution of h with a noise prediction filter impulse response, is being modelled. This modelling is achieved in part by a trellis, and in part by backtracing survivor paths in the detector based on the trellis.

The invention relates to super-trellis based noise predictive detection for high density optical storage, where a runlength limited or RLL encoder, a non-return-to-zero inverted or NRZI precoder, a partial response or PR channel, and a noise predictor or NP together are interpreted as one equivalent RLL-NRZI-PR-NP channel.

For combining the RLL decoding trellis with the NRZI-PR channel, two approaches are shown which extend the RLL decoding trellis into an RLL-NRZI-PR-NP super-trellis by either looking backward or looking forward into the RLL decoding trellis. Investigating both of these is advantageous, because depending on the underlying RLL decoding trellis, either the first or the second approach may turn out to be less complex and thus preferable.

To maintain a reasonable detector complexity, reduced-state noise predictive detectors are derived. Three different d=1 RLL codes are compared with respect to the complexity of noise predictive detectors, showing the complexity advantage of our recently designed d=1, k=9 RLL code. Simulation results show that bit error rate performance gain obtained by the proposed detector increases as storage density increases.

The invention advantageously provides an improved bit error rate (BER) performance, compared to detectors without noise prediction, especially for high-density storage. It also provides an improved soft-output quality enabling a more effective soft information exchange between the super-trellis detector with an outer soft-in soft-out decoder.

FIG. 5 and FIG. 6 depict Noise prediction (and compensation) for PR-channels with an impulse response of memory length L, meaning that an FIR filter equivalent would need a chain of L delay elements connected in series. An equivalent and sometimes preferable description of the impulse response is that of a coefficient vector h, which then has dimensionality L+1. As an example, an impulse response of [1,2,2,2,1] requires L=4 delay elements, the vector representation has dimensionality 5.

FIG. 5 and FIG. 6 are related to the structure shown in FIG. 3 of [1].

If noise prediction is applied, the effective length of the impulse response g of the overall system will generally be extended or increased, compared to that of the original impulse response h, according to

g=conv(h, [1, −p]) of length Lp=L+M,

where p denotes the predictor impulse response or predictor coefficient vector of length resp. dimensionality M.

Same as in [1], it is assumed here that noise predictor coefficients are computed based on the autocorrelation of the total distortion at the output of the PR-equalizer, see Appendix A and Eq. A.4 of [1].

Completely modelling the longer overall impulse response will need an increased number of trellis states and branches, so that, without further measures, detector complexity will rise significantly.

In [1] a traceback method for Viterbi detection is proposed for state reduction through ISI cancellation by delayed decision feedback. ISI stands for Inter-Symbol-Interference. Here, too, the design parameter K denotes the number of coefficients handled within the detector and directly governs trellis complexity, i.e. the number of states and branches. For example, K=L means that the PR-cannel ISI is completely reproduced or dealt with within the detector trellis. Any additional or residual ISI “induced” through noise prediction has to be cancelled through decision feedback by backtracing survivors in the trellis. For K<L, part of the channel ISI is also compensated through decision feedback. In cases of K>L, at least parts of the ISI “induced” through noise prediction is also compensated or dealt with within the detector states and branches.

This invention extends this approach to Super-trellis detectors.

Table 1 shows the number of trellis states and the number of branches needed for implementing three different channel decoders at different values of the design parameter K. The channel codes are:

denoted as “(1,7)-PP”, the (1,7)-PP code used on BluRay-Disc,

denoted as “d1k10r2”, the (d=1, k=10, r=2) RMTR RLL code presented in W. Coene et al, A new d=1, k=10 soft-decodable RLL code with r=2 RMTR constraint and a 2-to-3 PCWA mapping for DC-control, Optical Data Storage Topical Meeting, 2006, pp 168-170, and,

denoted as “d1k9r5”, a (1,9) RLL code with RMTR=5 we have designed with a remarkably low detector complexity.

Table entries are shown as number pairs “a/b”, where “a” stands for the number of trellis states, and “b” stands for the number of branches.

In an embodiment of the invention, joint detection and channel decoding of binary data is achieved by steps of:

receiving a sequence of channel output samples,

applying a PR equalizer,

applying a noise predictor, and

applying a trellis-based detector which employs a single super-trellis which describes the combined effect of applying serially the signal processing steps of RLL encoding, NRZI preceding, channel, PR equalizer, and Noise Predictor.

PR channel targets include (1,1), (1,2,1), (1,2,2,1), (1,2,2,2,1), and (0.17, 0.5, 0.67, 0.5, 0.17).

### BRIEF DESCRIPTION OF FIGURES

FIG. 1 shows an information transmission model for optical storage systems that is used in this invention.

Table 1 shows, as a measure for complexity, the number of trellis states and branches, for RLL-NRZI-PR-NP super-trellises according to this invention, based on a (1,7) -PP code, a d1k10r2 code, and a d1k9r5 code, at different values of the design parameter K.

FIG. 2(a) shows the Bit Error Rate BER over the SNR for the RLL-NRZI-PR-NP super-trellises according to this invention, based on the (1,7)-PP code, the d1k10r2 code, and the d1k9r5 code at different settings assuming a storage capacity of 25 GB.

FIG. 2(b) shows the Bit Error Rate BER over the SNR for the RLL-NRZI-PR-NP super-trellises according to this invention, based on the (1,7)-PP code, the d1k10r2 code, and the d1k9r5 code at different settings assuming a storage capacity of 30 GB.

FIG. 3 shows the Bit Error Rate BER over the SNR for the RLL-NRZI-PR-NP super-trellises according to this invention, based on the (1,7)-PP code, the d1k10r2 code, and the d1k9r5 code at different settings assuming a storage capacity of 35 GB.

FIG. 4(a) shows the Bit Error Rate BER over the SNR for the RLL-NRZI-PR-NP super-trellis according to this invention based on the (1,7)-PP code at different values of the design parameter K, assuming a storage capacity of 35 GB.

FIG. 4(b) shows the Bit Error Rate BER over the SNR for the RLL-NRZI-PR-NP super-trellis according to this invention based on the d1k9r5 code at different values of the design parameter K, assuming a storage capacity of 35 GB.

FIG. 4(c) shows the Bit Error Rate BER over the SNR for the RLL-NRZI-PR-NP super-trellis according to this invention based on the d1k10r2 code at different values of the design parameter K, assuming a storage capacity of 35 GB.

FIG. 5 and FIG. 6 show, in block diagram form, an arrangement, similar to FIG. 3 of [1], for Noise Prediction and compensation according to this invention, in a PRML detector.

### DESCRIPTION OF EMBODIMENTS

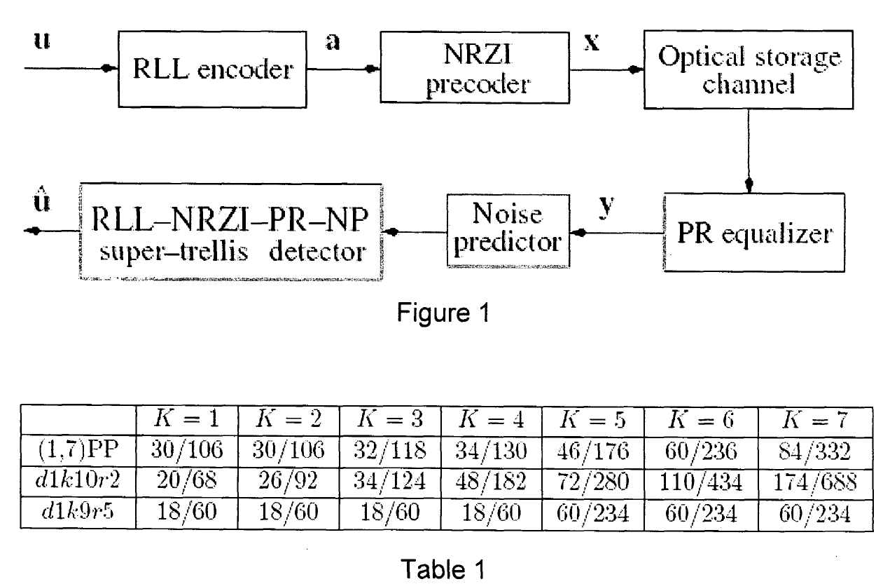

FIG. 1 shows the information transmission model for optical storage systems that is used here, where the Braat-Hopkins model is applied to optical storage channels using Blu-ray disc (BD) optics. Moreover, additive white Gaussian noise is present before the PR equalizer. The output signal of PR-equalizer is as follows:

$$y [ k ] = {\sum }_{l = 0}^{L} {h}_{l} x [ k - l ] + e [ k ] ,$$

where {h₁, 0≦l≦L} denote PR-target coefficients with L as PR-channel memory length, {x[k]} are channel bits after NRZI conversion, and e[k] is colored noise. Moreover, {z[k]} are noiseless PR channel outputs.

In the descibed embodiments, rate 2/3 RLL encoders are considered that have u₂ₙ²ⁿ⁺¹ as two data bits and a₃ₙ³ⁿ⁺² as three corresponding channel bits at index n. In this, the notation vₐ^{b} denotes a sequence v from time index a to time index b. Given the phase reference x[3n−1], NRZI data symbols x₃ₙ³ⁿ⁺² can be obtained from a₃ₙ³ⁿ⁺² using NRZI conversion. Consequently, u₂ₙ²ⁿ⁺¹ produces three noiseless PR channel outputs, z₃ₙ³ⁿ⁺², which depend on x_{3n-L}³ⁿ⁺² due to the PR-channel memory.

RLL encoder, NRZI converter and PR-channel constitute an equivalent RLL-NRZI-PR channel, which has u₂ₙ²ⁿ⁺¹ as input and z₃ₙ³ⁿ⁺² as output. The RLL-NRZI-PR super-trellis can be constructed by expanding the RLL decoding trellis either in the backward or in the forward direction.

A Looking Backward Approach to Derive the Extended Trellis

For a looking-backward approach [2,3,4], states in the super-trellis are defined as

s′[n]=(s[n],x_{3n-L}³ⁿ⁻¹), (1)

where s[n] is a state in the RLL decoding trellis and state transitions thereof, denoted as s[n]→s[n+1], determine three NRZ data symbols a₃ₙ³ⁿ⁺². Consequently, state transitions s′[n]→s′[n+1] will provide NRZI data symbols x_{3n-L}³ⁿ⁺², which are required to evaluate z₃ₙ³ⁿ⁺². In order to determine x_{3n-L}³ⁿ⁻¹ in s′[n], what we need is to obtain NRZ data symbols a_{3n-L+1}³ⁿ⁻¹, given the phase reference x[3n−L]. This can be accomplished if we trace back the RLL decoding trellis from s[n] by N_{b} steps. Since each tracing back step provides three past NRZ data symbols, the following condition should be fulfilled:

$$3 ( n - {N}_{b} ) \leq 3 n - L + 1 ⇒ {N}_{b} = ⌈ \frac{L - 1}{3} ⌉ , \qquad ( 2 )$$

where [a] denotes the smallest integer not less than a. Let L_{b}=3N_{b}, then N_{b}-step tracing back provides an NRZ data set A_{b}(s[n])={a_{3n-L}_{_{b}}³ⁿ⁻¹|s[n]}, which includes all possible NRZ data sequences a_{3n-L}_{_{b}}³ⁿ⁻¹ that merge into a specific state s[n]. For NRZ to NRZI conversion, there are two possible phase references x[3n−L_{b}−1]=+1 or x[3n−L_{b}−1]=−1. Therefore, we obtain the NRZI data set X_{b}(s[n])={x_{3n-L}_{_{b}}₋₁³ⁿ⁻¹|s[n]} with |X_{b}(s[n])|=2|A_{b}(s[n])|, where |A| denotes the cardinality of the set A. Based on X_{b}(s[n]), the set of data symbols x_{3n-L}³ⁿ⁻¹ can easily be found for a specific s[n], which is used to define s′[n] in eq. (1).

A Looking Forward Approach to Derive the Extended Trellis

Alternatively, we may look forward N_{f} steps diverging from s[n]. Three noiseless PR-channel outputs z_{3(n+L}_{_{f}}₎^{3(n+L}^{_{f}}⁾⁺² may be employed for the evaluation of branch metrics, which depend on NRZI data symbols x_{3(n+L}_{_{f}}_{)-L}^{3(n+L}^{_{f}}⁾⁺². Note that for N_{f}=0, we get z₃ₙ³ⁿ⁺² as before. Since state transitions in the RLL decoding trellis s[n]→s[n+1] deliver a₃ₙ³ⁿ⁺² and we take the phase reference x[3n−1] into account, the following condition has to be fulfilled:

$$3 ( n + {N}_{f} ) - L \geq 3 n - 1 ⇒ {N}_{f} = ⌈ \frac{L - 1}{3} ⌉ . \qquad ( 3 )$$

Therefore, states in a looking-forward super-trellis are defined as

s′[n]=(s[n],x_{3(n+N}_{_{f}}_{)-L}^{3(n+N}^{_{f}}⁾⁻¹), (4)

where state transitions s′[n]→s′[n+1] provide NRZI data symbols x_{3(n+L}_{_{f}}_{)-L}^{3(n+L}^{_{f}}⁾⁺². The determination of x_{3(n+L}_{_{f}}_{)-L}^{3(n+L}^{_{f}}⁾⁻¹ for s′[n] in Eq. (4) can be accomplished similarly as the procedure presented for the looking-backward approach.

Super-Trellis Based Noise Predictive Detection

In the presence of a noise predictor NP, the equivalent channel up to the bit detector is composed of an RLL encoder, an NRZI precoder, a PR channel, and a Noise Predictor, all of which is referred to as an “RLL-NRZI-PR-NP channel” in the sequel, as also shown in FIG. 1.

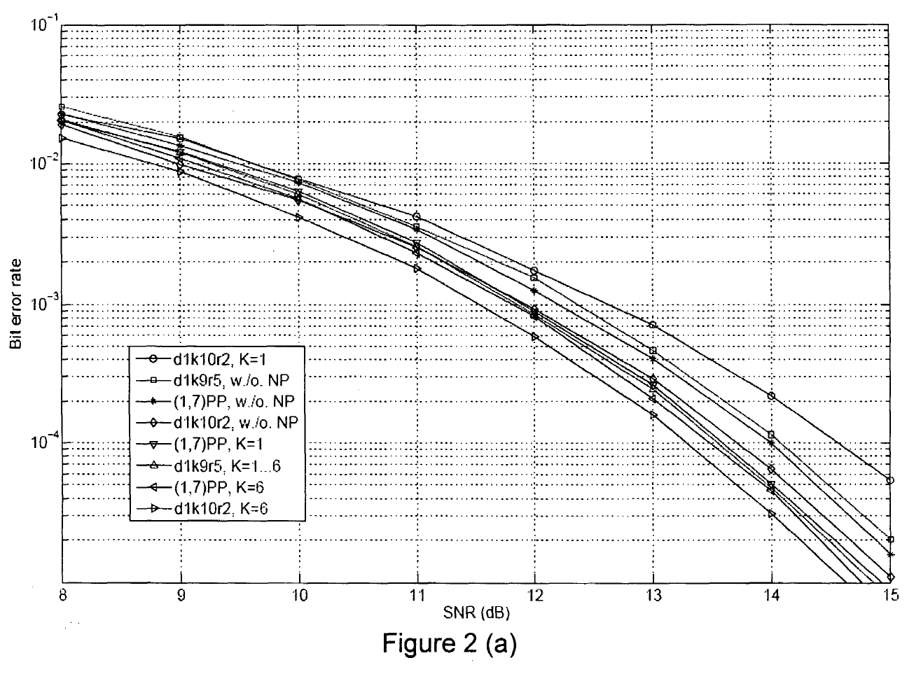

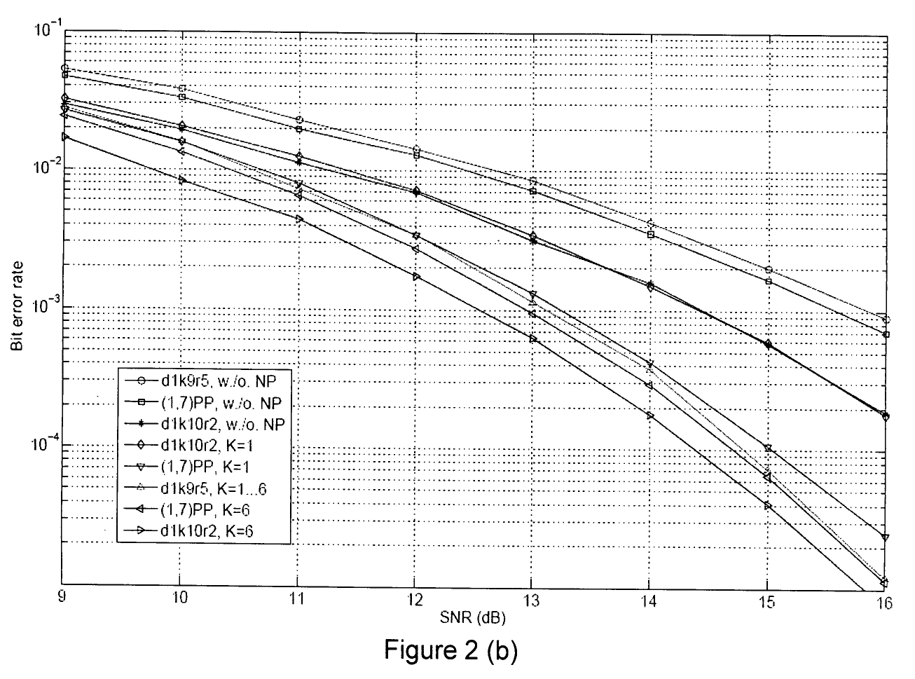

Let p=[p₁, . . . , p_{M}] denote a noise prediction vector, the PR-NP channel shown in FIG. 2 can be described as

g=conv(h,[1,−p)],

where conv( ) stands for discrete-time convolution and h represents the PR target. Moreover, the channel memory length of the PR-NP channel is Lₚ=L+M. Accordingly, states in the RLL-NRZI-PR-NP super-trellis are defined as (s[n],x_{3n-L}_{ₚ}³ⁿ⁻¹) if looking backward the RLL decoding trellis, or as (s[n],x_{3(n+L}_{_{f}}_{)-L}_{ₚ}^{3(n+L}^{_{f}}⁾⁻¹) for a looking-forward approach.

Instead of employing an explicit noise predictor in front of the detector designed for RLL-NRZI-PR-NP channel, we may also employ detectors designed for RLL-NRZI-PR channel with embedded noise prediction. Both approaches are theoretically equivalent, but they are different from the viewpoint of implementation. As shown in ref. 1, the approach with an explicit noise predictor provides implementation advantages.

To trade off the computational complexity and performance of an RLL-NRZI-PR-NP super-trellis based detector, a reduced-state super-trellis can be derived by a design parameter K ε└1,Lₚ┘, where states in the reduced-state super-trellis are defined either as (s[n],x_{3n-K}³ⁿ⁻¹) or as (s[n],x_{3(n+L}_{_{f}}_{)-K}^{3(n+L}^{_{f}}⁾⁻¹). Note that a phase reference is always required for NRZ-to-NRZI conversion, therefore, K≧1. State transitions in the reduced-state super-trellis only provide K+3 NRZI data symbols. In order to obtain the other Lₚ−K data symbols, delayed decision feedback sequence estimation [6] can be applied for super-trellis, where surviving paths for individual states in the reduced-state super-trellis are traced back by Nₚ steps. Since each step during tracing back provides three past decisions on NRZI symbols, we have

$${N}_{f} = ⌈ \frac{{L}_{p} - K}{3} ⌉ .$$

For SISO reduced-state detectors, a SOVA or Max-Log-MAP algorithm should be employed, since there are survivors for both algorithms enabling a trace-back. In contrast, no survivor is available using a BCJR or a Log-MAP algorithm.

We considered the (1,7)-PP code adopted for BD standards, a (1,10) code with a repeated minimum transition runlength (RMTR) constraint of 2 (shortly termed as d1k10r2 code) [7], and a (1,9) code [8] with an RMTR constraint of 5 that we have designed (denoted as d1k9r5 code) with a decoding state transition table given in Table 2. The decoding state transition table for the (1,7)-PP code was included in [4], and for the d1k10r2 code the RLL decoding trellis can be derived from its encoding tables [7]. It was verified that the looking-backward approach provides a less complex super-trellis for both the (1,7)-PP code and the d1k10r2 code, while for the d1k9r5 code the looking-forward approach is preferable. Table 1 compares the RLL-NRZI-PR-NP super-trellis complexity for these three codes with respect to the number of states/branches. For K≦4, the super-trellis employing the d1k9r5 code has a significantly lower complexity, while for K≧3 the super-trellis employing the d1k10r2 code has a higher complexity. In addition, the super-trellis employing the d1k9r5 code has the same complexity for K≦4 and for K ε[5,7], since each state in the RLL decoding trellis has three unique upcoming RLL bits, refer to the following Table 2.

TABLE 2
RLL decoding trellis state transition table
for the d1k9r5 code.

| Previous | Current data bits | Current RLL bits | Current state |
|---|---|---|---|
| state s[n] | u₂ₙ²ⁿ⁺¹ | a₃ₙ³ⁿ⁺² | s[n + 1] |
| S0 | 01 | 000 | S1 |
| S0 | 01 | 000 | S2 |
| S0 | 01 | 000 | S3 |
| S0 | 01 | 000 | S5 |
| S0 | 11 | 000 | S8 |
| S1 | 10 | 001 | S1 |
| S1 | 10 | 001 | S2 |
| S1 | 10 | 001 | S6 |
| S2 | 10 | 010 | S0 |
| S2 | 11 | 010 | S1 |
| S2 | 11 | 010 | S2 |
| S2 | 11 | 010 | S3 |
| S2 | 11 | 010 | S5 |
| S3 | 00 | 100 | S0 |
| S3 | 01 | 100 | S1 |
| S3 | 01 | 100 | S2 |
| S3 | 01 | 100 | S3 |
| S3 | 01 | 100 | S5 |
| S4 | 11 | 000 | S3 |
| S4 | 11 | 000 | S5 |
| S5 | 00 | 101 | S1 |
| S5 | 00 | 101 | S2 |
| S5 | 00 | 101 | S6 |
| S6 | 00 | 000 | S1 |
| S6 | 00 | 000 | S2 |
| S6 | 00 | 000 | S3 |
| S6 | 00 | 000 | S5 |
| S6 | 11 | 000 | S7 |
| S7 | 00 | 000 | S4 |
| S8 | 00 | 000 | S2 |

Simulation Results

A linear equalizer based on the minimum mean square error (MMSE) principle with 19 coefficients is employed as PR equalizer, where the PR target is selected as h=[1, 2, 2, 1]. For MMSE prediction [1], the prediction order is chosen as M=20 resulting in Lₚ=23, and joint bit detection and RLL decoding is carried out using the Max-Log-MAP algorithm, which is appropriately modified for super-trellis based detectors. For simulations, signal-to-noise ratio (SNR) is defined as the reciprocal of the additive white Gaussian noise variance.

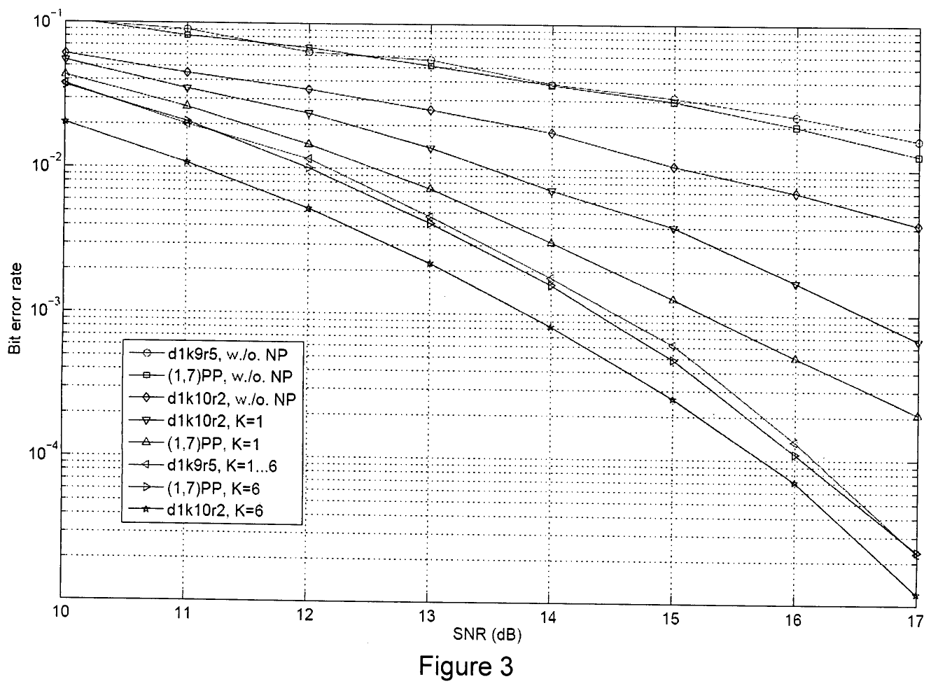

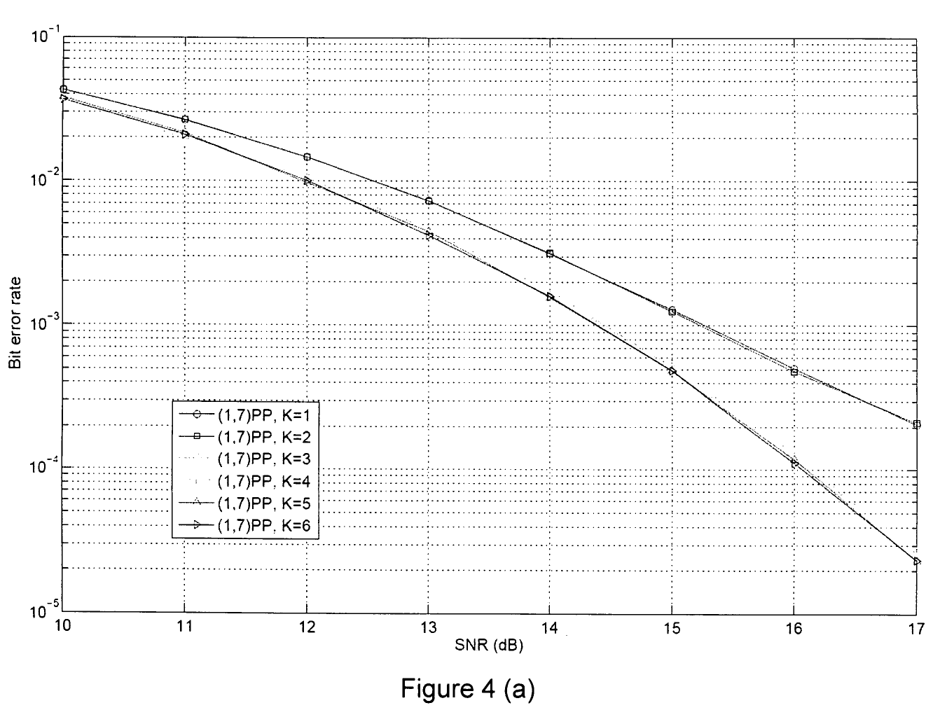

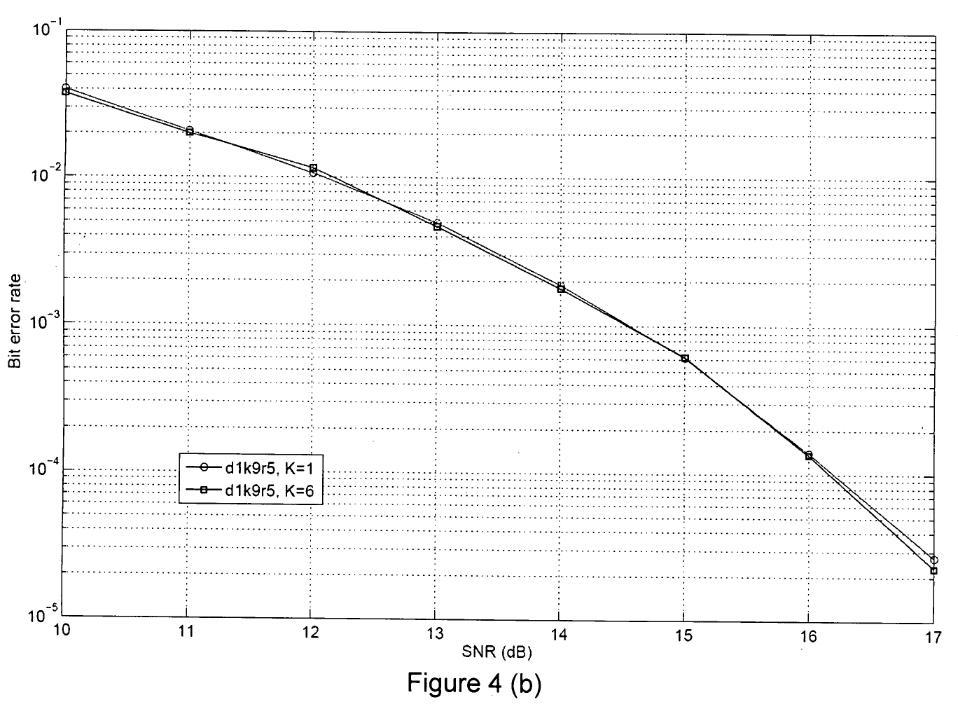

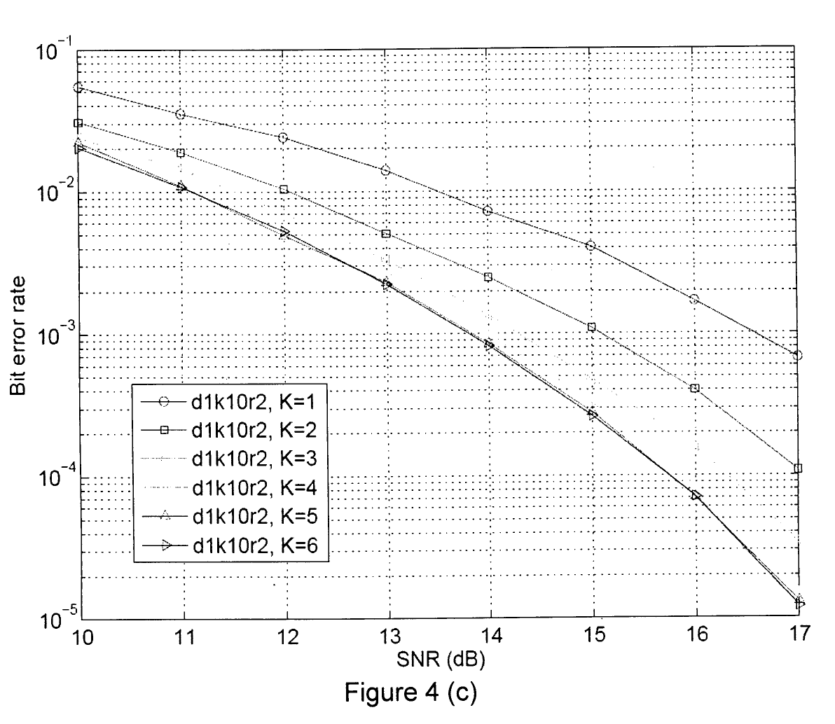

BER performance is compared between RLL-NRZI-PR-NP super-trellis based detectors and the known RLL-NRZI-PR super-trellis based detector, where the complexity of the latter is similar to the former detectors with K=3. As shown in FIGS. 3 and 4, the performance gap between RLL-NRZI-PR-NP super-trellis based detectors and the RLL-NRZI-PR super-trellis based detector increases as the storage density increases from 25 GB to 35 GB. Moreover, the gap between a detector with a small K and a detector with a large K also increases with the increased storage density for the (1,7)-PP code and for the d1k10r2 code. For the d1k9r5 code, there is no performance difference for detectors with K ε[1,6]. Therefore, only the BER performance for K=6 is shown in FIGS. 3 and 4 for the d1k9r5 code.

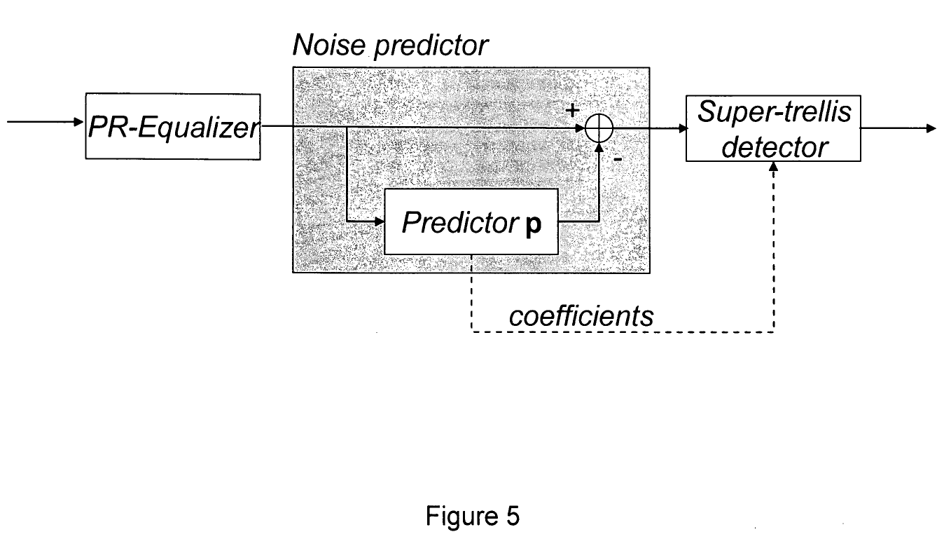

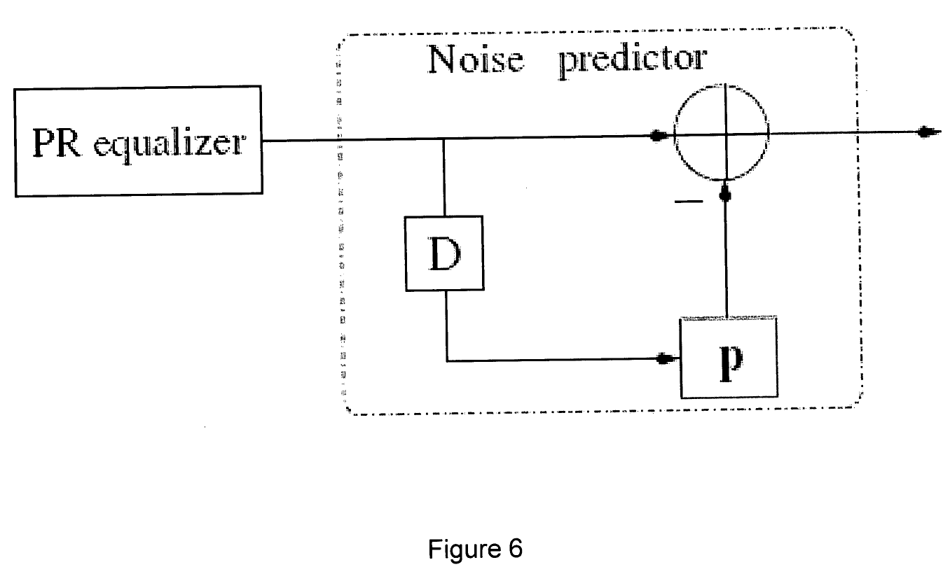

Under the 35 GB capacity, as shown in FIG. 5, for the (1,7)-PP code no performance improvement is visible by increasing the detector complexity if K≧3. For the d1k10r2 code, the performance improves gradually with increased complexity, while no further improvement was observed for K≧4. Although a similar performance has been obtained for the (1,7)-PP code with K=3 and the d1k9r5 code with K≦4, the detector complexity of the d1k9r5 code is only approximately one half of that of the (1,7)-PP code. In the case of the d1k10r2 code, the detector with K=4 provides a slight performance improvement, while the detector complexity is significantly higher, refer to Table 1.

Incorporating noise prediction, RLL-NRZI-PR-NP super-trellis based bit detectors were investigated. For the super-trellis construction, we showed that both looking-forward and looking-backward the RLL decoding trellis are possible, where one of these two approaches is advantageous with respect to super-trellis complexity. With increased storage density, noise prediction based detectors provide increased performance gain. In the presence of an outer SISO channel decoder such as a turbo decoder or a LDPC decoder, the turbo principle, i.e., iterative exchange of extrinsic information between the inner SISO RLL-NRZI-PR-NP detector and the outer SISO channel decoder, can be applied straightforwardly. Systems employing the d1k9r5 code with a lower detector complexity have a similar performance as systems employing the (1,7)-PP code, while systems employing the d1k10r2 code have a better performance at the expense of a higher detector complexity.

### REFERENCES

[1] J. D. Coker, E. Eleftheriou, R. L. Galbraith, and W. Hirt: IEEE Trans. Magn. 34 (1998) 110.

[2] E. Yamada, T. Iwaki and T. Yamaguchi: Jpn. J. Appl. Phys. 41 (2002) 1753.

[3] F. Zhao, G. Mathew, and B. Farhang-Boroujeny: Proc. IEEE ICC, 2003, p. 2919.

[4] T. Miyauchi, Y. Shinohara, Y. Iida, T. Watanabe, Y. Urakawa, H. Yamagishi, and M. Noda: Jpn. J. Appl. Phys. 44 (2005) 3471.

[5] K. Cai, G. Mathew, J. W. M. Bergmans and Z. Qin: Proc. IEEE ICCE, 2003, p. 324.

[6] W. Coene, A. Hekstra, B. Yin, H. Yamagishi, M. Noda, A. Nakaoki, and T ˜Horigome: Proc. SPIE 6282 (2006) 62820X.

[7] O. Theis, X.-M. Chen, D. Hepper, and G. Pilard: Tech. Dig. ISOM/ODS, 2008, p. 425.

1. Method for joint detection and channel decoding of binary data, applying a trellis-based detector in which a single super-trellis describes the signal processing of an RLL encoding stage, an NRZI preceding stage, the channel, a PR equalizer stage, and a Noise predictor stage.

2. A method according to claim 1, where the trellis-based detector uses, for complexity reasons, a trellis of reduced number of states, together with a traceback of surviving paths according to a delayed decision feedback approach.

3. A method according to claim 1, wherein the RLL encoding stage implememnts an RLL code having a lower runlength of 1 and an upper runlength of 9.

4. A method according to claim 1, wherein the PR equalizer stage filters the channel output samples such that the filtered samples achieve a target impulse response of (1,2,2,2,1).

5. A method according to claim 1, wherein the Noise predictor stage performs a convolution of the output of the PR equalizer with an FIR prediction filter and subtracts the result of the convolution from the output of the PR equalizer.

6. A SISO trellis-based detector for joint channel detection and RLL decoding, whose trellis comprises the combination of a PR channel trellis and an RLL code trellis, wherein the trellis also incorporates a noise prediction filter.

7. A method for joint data detection and channel or ECC decoding, wherein a data detection step that uses a trellis-based detector, and a channel or ECC decoding step that uses a SISO channel or ECC decoder are iteratively repeated according to a turbo principle, soft information is exchanged between the detection step and the decoding step in both directions, and the trellis of the data detection step incorporates a noise prediction filter.

8. A method according to claim 7, wherein the SISO channel or ECC decoder is a message passing decoder.
